(19) United States
(12) Patent Application Publication
(10) Pub. No.: US 2008/0002362 A1
(43) Pub. Date: Jan. 3, 2008

(54) Electronic apparatus

(75) Inventor: Junichi Ishimine, Kawasaki (JP)

Correspondence Address: ARENT FOX LLP, 1050 CONNECTICUT AVENUE, N.W., SUITE 400, WASHINGTON, DC, 20036, US

(73) Assignee: FUJITSU LIMITED

(21) Appl. No.: 11/896,808

(22) Filed: Sep. 6, 2007

Related U.S. Application Data
(63) Continuation of application No. PCT/JP05/05735, filed on Mar. 28, 2005.

(51) Int. Cl. H05K 7/20

(52) U.S. Cl. 361/695; 361/724

(57) ABSTRACT

An electronic apparatus is disclosed that is configured so that cooling air flows between a front face and a rear face of a rack. The electronic apparatus includes an electronic device that is provided with an operations portion at a longitudinal side face of a device main body and is cooled by the cooling air flowing inside the device main body in a longitudinal direction thereof, a device mount member in which the electronic device is mounted so that the longitudinal direction of the device main body is aligned with a fore-aft direction of the rack, and a slide mechanism that slides the device mount member in the fore-aft directions of the rack.

### CROSS-REFERENCE TO RELATED APPLICATIONS

This application is a U.S. continuation application filed under 35 USC 111(a) claiming benefit under 35 USC 120 and 365(c) of PCT application JP2005/005735, filed on Mar. 28, 2005, the entire contents of which are incorporated herein by reference.

### BACKGROUND OF THE INVENTION

1. Field of the Invention

The present invention generally relates to an electronic apparatus, and particularly relates to an electronic apparatus with an air-cooling device provided in a rack.

2. Description of the Related Art

In recent years, it has become common to mount independent electronic devices with various functions on an area equally divided at a standardized pitch in an electronic apparatus such as a communication apparatus. More specifically, it has become common to mount electronic devices including server products, storage products, and network products together in a rack. Along with this trend, various structures have been disclosed that mount electronic devices in a rack so as to suit characteristics of each electronic device (see Patent Document 1).

Generally, the electronic devices to be mounted in the rack have their own cooling structures. A typical cooling structure of the rack is to intake air from the front and exhaust the air from the rear. In accordance with this cooling structure of the rack, the conventional electronic devices such as server products, storage products, etc., (hereinafter referred to as “storage products, etc.”) that are designed to be mounted in the rack also have the configuration of intake from the front and exhaust from the rear. In such an electronic device, cooling air inside a device main body of the electronic device flows in the fore-aft direction (the longitudinal direction orthogonal to the device main body).

<Patent Document 1> Japanese Patent Laid-Open Publication No. 2001-144462

As mentioned above, in these years, storage products, etc., and network products have been often mounted together in a rack. The network products have cooling structures different from those of the storage products, etc. That is, the network products cannot have intake ports in the front faces of the device main bodies because cables are attached to the front faces of the device main bodies. This is discussed below with reference to FIG. 1.

FIG. 1 is a diagram showing an electronic apparatus 1 in which an electronic device 6, which is a network product, is mounted in a rack 2. The rack 2 comprises a rack main body 3, a rack front door 4, and a rack rear door 5. It is to be noted that FIG. 1 is a configuration diagram plan view of the electronic apparatus 1, wherein the lower side of the drawing corresponds to the front side of the electronic apparatus 1 while the upper side of the drawing corresponds to the rear side of the electronic apparatus 1.

Plural angle mounts 8 are disposed in the rack 2. The electronic device 6 is fixed to the angle mounts 8 at the front side. As the electronic device 6 is a network product, plural cables 7 are removably attachable thereto at the front side thereof. The electronic device 6 is mounted in the rack 2 in a manner such that an operations face 6C of the electronic device 6, to which the cables 7 are attachable, opposes the rack front door 4. In order to have a space for attaching and detaching the cables 7, the operations face 6C is aligned along the longitudinal direction (the direction of the arrows X1 and X2).

As mentioned above, a typical cooling structure inside the rack 2 is intake from the front and exhaust from the rear. That is, cooling air 9A flows in the arrow Y direction. However, the electronic device 6 as a network product cannot have a cooling air intake port in the operations face 6C as a longitudinal face, because the cables 7 are attached to the operations face 6C. Therefore, an intake port is provided in a left side face 6A of the device main body of the electronic device 6, and an exhaust port is provided in a right side face 6B of the device main body.

Accordingly, cooling air 9B inside the device main body of the electronic device 6 flows in the longitudinal direction (the direction of the arrows X1 and X2), which is different from the direction in which the cooling air 9A flows inside the rack 2. This configuration prevents the electronic device 6 from being properly cooled.

Another problem with the cooling structure of FIG. 1 is that, since the operations face 6C is attached to the angle mounts 8, the passage for the cooling air 9A to the intake port (the left side face 6A) is narrow, which prevents fresh cooling air 9A from being supplied into the electronic device 6. Moreover, the heated cooling air 9B exhausted from the right side face 6B returns to the intake port in the left side face 6A of the electronic device 6 inside the rack 2 as indicated by the arrows 9C, which prevents efficient cooling.

FIG. 4 is a diagram generally showing an electronic apparatus 10 in which the electronic device 6 of FIG. 1 as a network product is mounted in a rack 12. The electronic apparatus 10 is configured so that air is introduced from an opening in a rack front door 14, passes through electronic devices, and is exhausted from a rack rear door 15. Generally, electronic devices are mounted in the rack 12 with no space therebetween. If there is a space therebetween, a blocking plate 100 for isolating an intake area from an exhaust area is provided in order to prevent the exhaust air of the electronic devices from returning to the front side of the electronic devices and thereby enable appropriate cooling.

The electronic device 6 of FIG. 1 corresponds to each of network products 11B of FIG. 4. In some cases, as shown in FIG. 4, accommodating spaces 101 for accommodating cables of the network products 11B are provided at the lower side (or the upper side) of the corresponding network products 11B. The cable accommodating spaces 101 short-circuit the intake area and the exhaust area, so that the exhaust air of the electronic devices returns to the intake ports of the electronic devices. This results in inefficient cooling.

### SUMMARY OF THE INVENTION

The present invention aims to provide an improved and useful electronic apparatus that may solve one or more of the problems in the related art described above.

More specifically, the present invention aims to provide an electronic apparatus wherein various electronic devices whose cooling air flow directions inside the device main bodies are different from each other can be mounted in a rack.

According to an aspect of the present invention, there is provided an electronic apparatus that is configured so that cooling air flows between a front face and a rear face of a rack. The electronic apparatus comprises an electronic device that is provided with an operations portion at a longitudinal side face of a device main body and is cooled by the cooling air flowing inside the device main body in a longitudinal direction thereof, a device mount member in which the electronic device is mounted so that the longitudinal direction of the device main body is aligned with a fore-aft direction of the rack, and a slide mechanism that slides the device mount member in the fore-aft directions of the rack.

According to this aspect of the present invention, even if the electronic device has a cooling air flow direction aligned with the longitudinal direction of the device main body thereof, since the electronic device is mounted so that the longitudinal direction of the device main body is aligned with the direction of the cooling air flowing inside the rack, the electronic device can be surely cooled. Further, although the operations portion is provided at the longitudinal side face of the device main body, the slide mechanism enables a sliding movement of the device mount member in the rack in the direction of the cooling air flowing inside the rack. Accordingly, although the operations portion does not oppose the front side of the rack, it is possible to operate on the operations portion by pulling out the device mount member. With this configuration, the electronic device is surely cooled while maintaining operability of the electronic device.

The slide mechanism may be removably attachable to the rack.

With this configuration, if the slide mechanism is removed, an electronic device having a different configuration (e.g. an electronic device whose cooling air flow direction inside a device main body is generally orthogonal to a longitudinal direction of the device main body) can be mounted.

In the above described electronic apparatus, it is preferable that a connector attachment portion be provided as the operations portion at the longitudinal side face of the device main body, and a wire accommodating space that accommodates a cable connected to the connector attachment portion be provided at a position opposing the connector attachment portion.

With this configuration, although the connector attachment portion as the operations portion is provided at the longitudinal side face of the device main body and does not oppose the rack front face, since the wire accommodating space is provided on the device mount member, the cable is disposed out of the way of other components in the rack.

In the above-described electronic apparatus, it is preferable that the device mount member be provided with a cable holding portion that restricts movement of the cable connected to the electronic device.

This configuration prevents the cable from being pulled out of the electronic device due to a movement of the device mount member.

In the above-described electronic apparatus, it is also preferable that the slide mechanism include a first rail fixed to the rack and a second rail slidable with respect to the first rail in the fore-aft directions of the rack.

In the above-described electronic apparatus, a network product may be used as the electronic device.

Further, in the above-described electronic apparatus, a first electronic device in which the cooling air flows in a device main body thereof in a longitudinal direction of the device main body thereof and a second electronic device in which the cooling air flows in a device main body thereof in a direction generally orthogonal to a longitudinal direction of the device main body thereof may be mounted together in the rack.

This configuration allows mounting electronic devices having various functions in a single rack, which enables a communication device to have more functions.

According to the above-described aspect of the present invention, the electronic device can be surely cooled even if the electronic device has a cooling air flow direction aligned with the longitudinal direction of the device main body thereof. Moreover, even if the operations portion is provided at the longitudinal side face of the device main body, it is possible to operate the operations portion by pulling out the device mount member. Therefore, the electronic device can be surely cooled while maintaining operability of the electronic device.

### BRIEF DESCRIPTION OF THE DRAWINGS

FIG. 1 is a configuration diagram schematically showing a related-art electronic apparatus;

FIG. 2 is a configuration diagram schematically showing an electronic apparatus wherein a device mount member is inserted in a rack according to one embodiment of the present invention;

FIG. 3 is a configuration diagram schematically showing an electronic apparatus wherein a device mount member is pulled out of a rack according to one embodiment of the present invention;

FIG. 4 is a perspective view showing an external appearance of an electronic apparatus according to one embodiment of the present invention;

FIG. 5 is an enlarged perspective view showing the vicinity of an electronic device of an electronic apparatus wherein a device mount member is inserted in a rack according to one embodiment of the present invention;

FIG. 6 is an enlarged perspective view showing the vicinity of an electronic device of an electronic apparatus wherein a device mount member is pulled out of a rack according to one embodiment of the present invention;

FIG. 7 is an enlarged perspective view showing a device mount member; and

FIG. 8 is an enlarged perspective view showing a device mount member in which an electronic device is mounted.

### DETAILED DESCRIPTION OF THE PREFERRED EMBODIMENT

The following provides exemplary embodiment of the present invention with reference to the accompanying drawings.

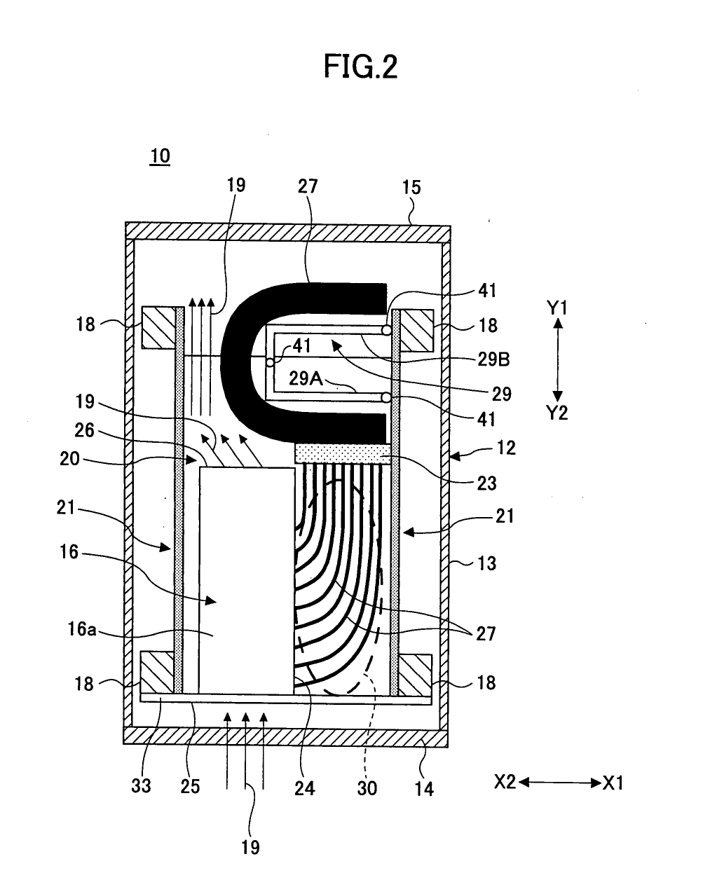

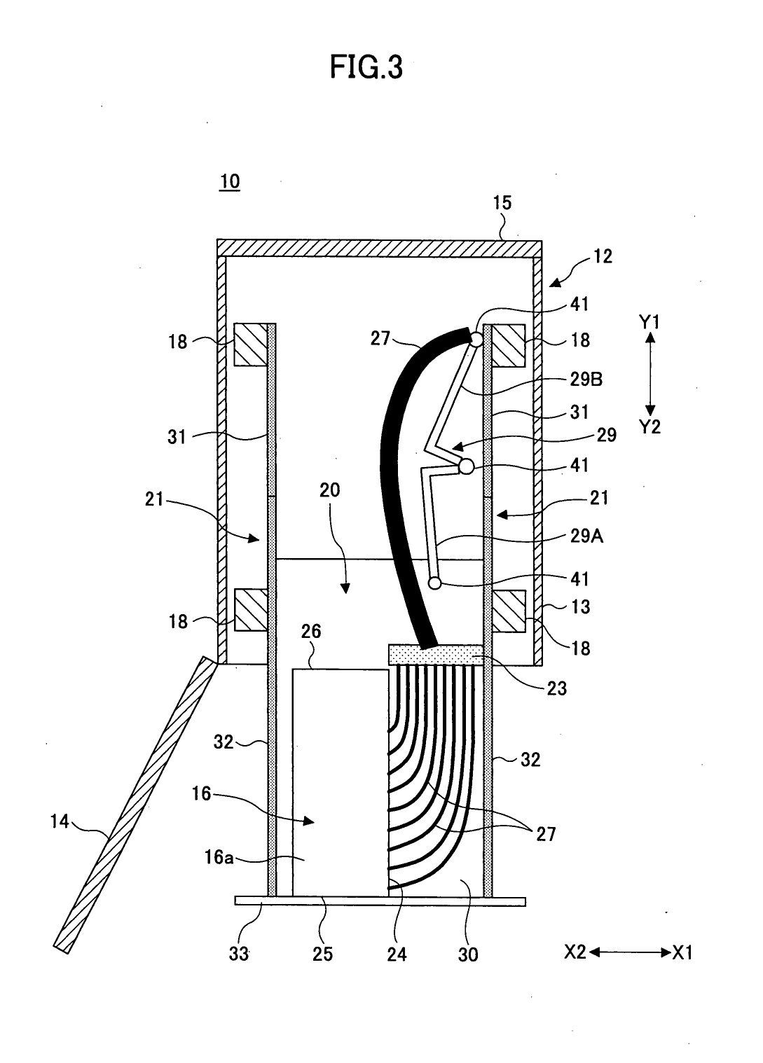

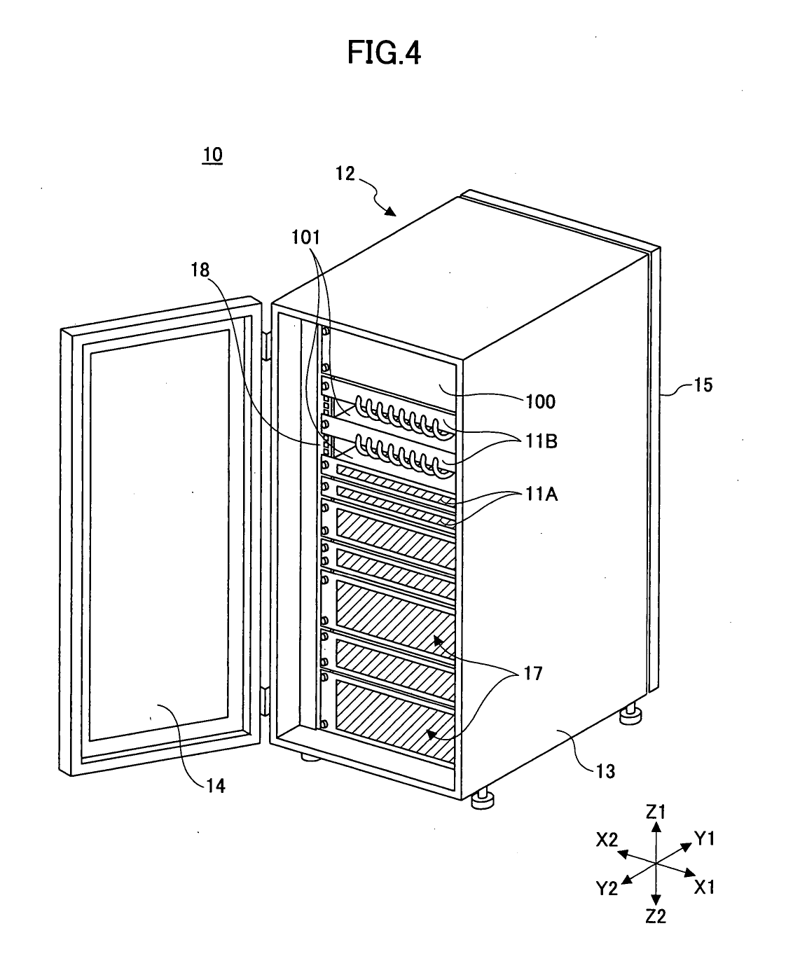

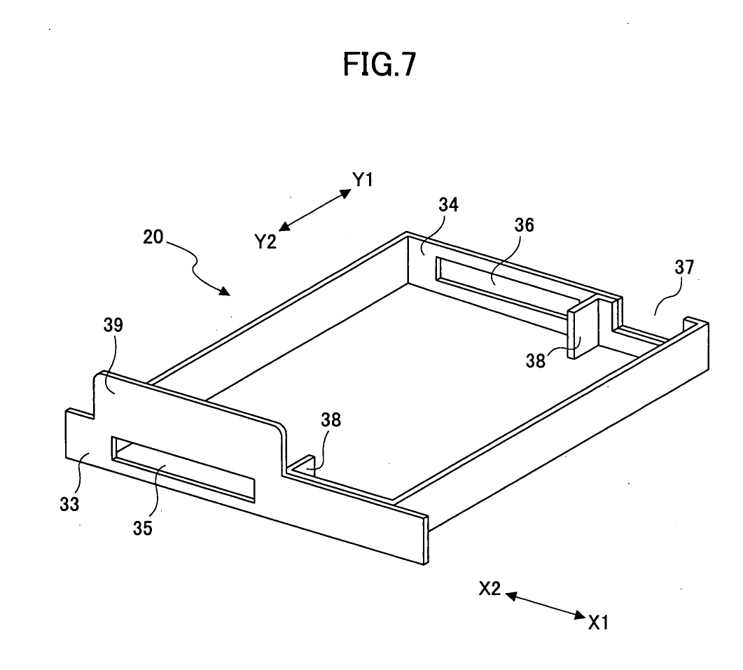

FIGS. 2 and 3 are diagrams each showing a basic configuration of an electronic apparatus 10 according to one embodiment of the present invention. FIGS. 4 through 8 are diagrams each illustrating details of the electronic apparatus 10. This embodiment exemplifies, as the electronic apparatus 10, a communication apparatus in which a network product 11A is mounted in a rack 12 together with a storage product 17, etc., as shown in FIG. 4.

The embodiment of the present invention is characterized by a structure for mounting the network products 11B in the rack 12. The structure for mounting the storage products 17, etc. in the rack 12 is not different from that of the related art; therefore, only the structure for mounting the network products 11B in the rack 12 is discussed below.

With reference to the attached drawings, the electronic apparatus 10 generally comprises the rack 12, an electronic device 16, a device mount member 20, a slider 21, signal cables 27, etc.

The rack 12, as shown enlarged in FIG. 4, comprises a rack main body 13 of a casing shape, a rack front door 14 that opens and closes the front side of the rack main body 13, and a rack rear door 15 that opens and closes the rear side (back side) of the rack main body 13. Plural angle mounts 18 (four angle mounts 18 in this embodiment) are disposed in the rack 12.

The rack 12 is provided with a blower (not shown). The electronic devices mounted in the rack 12 also have embedded blowers. Cooling air generated by these blowers flows from the front side to the rear side in the rack 12. That is, the rack 12 used in this embodiment also has a configuration of intake from the front and exhaust from the rear. The network products 11B and the storage products 17 stacked in the rack 12 are cooled by cooling air that flows from the front side to the rear side (in the direction of the arrow Y1).

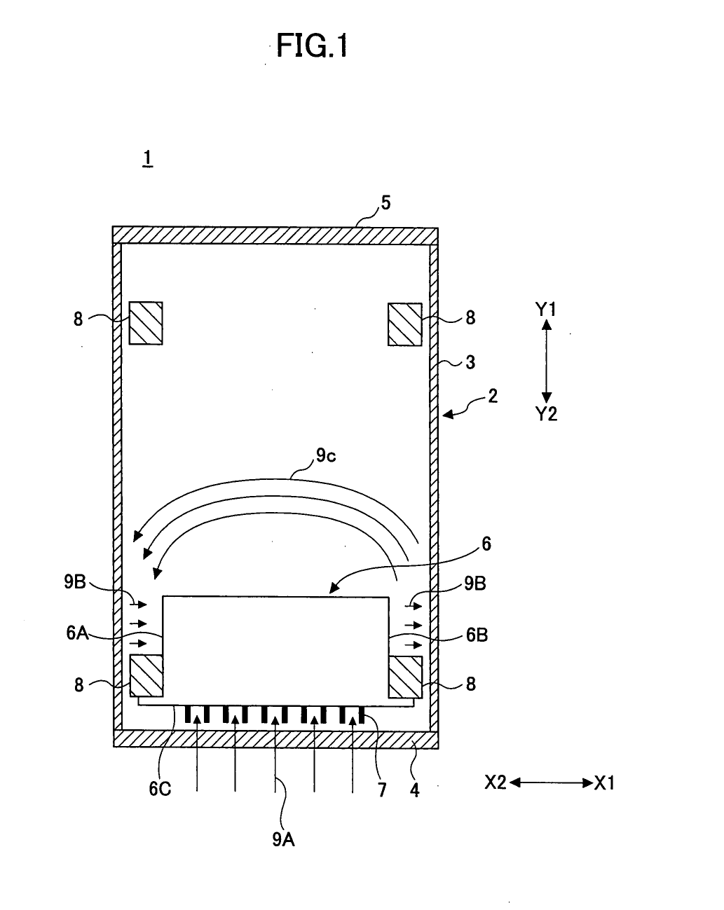

Similar to the related-art rack 2 of FIG. 1, the rack 12 allows the electronic device 16 (described below) to be mounted therein with an operations face 24 oriented in a direction parallel to the arrows X1 and X2. However, as described below, this embodiment is characterized by mounting the electronic device 16 in a manner such that the operations face 24 is aligned with the direction of the arrows Y1 and Y2.

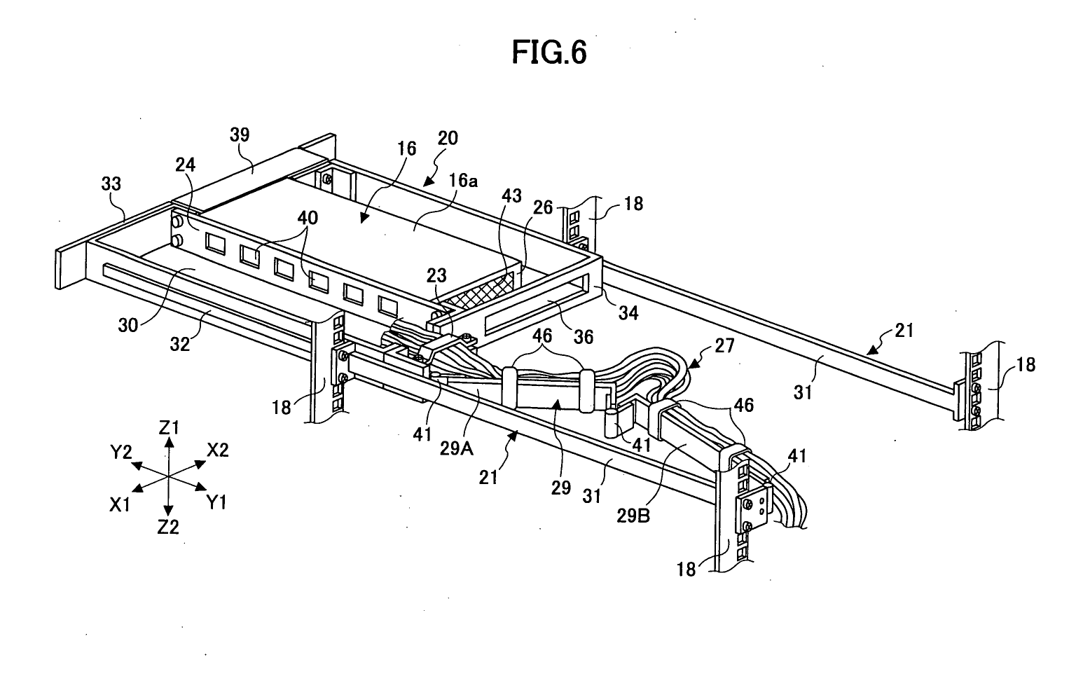

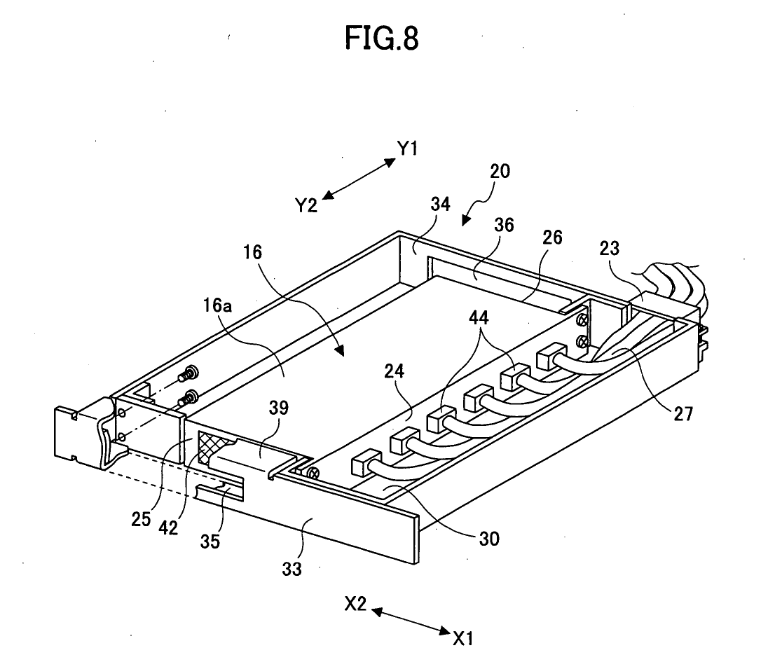

As shown enlarged in FIGS. 6 and 8, the device mount member 20 is formed in a rectangular shape, and has a bottom face, a front panel 33 at an end in the direction of the arrow Y2 (front side), and a back panel 34 at an end in the direction of the arrow Y1 (rear side). The front panel 33 is provided with an intake opening 35 and a bent portion 39. The back panel 34 is provided with an exhaust opening 36 and a cable exit portion 37. A device mount portion 38 to which the electronic device 16 is attached is formed on the inner side of each of the front panel 33 and the back panel 34.

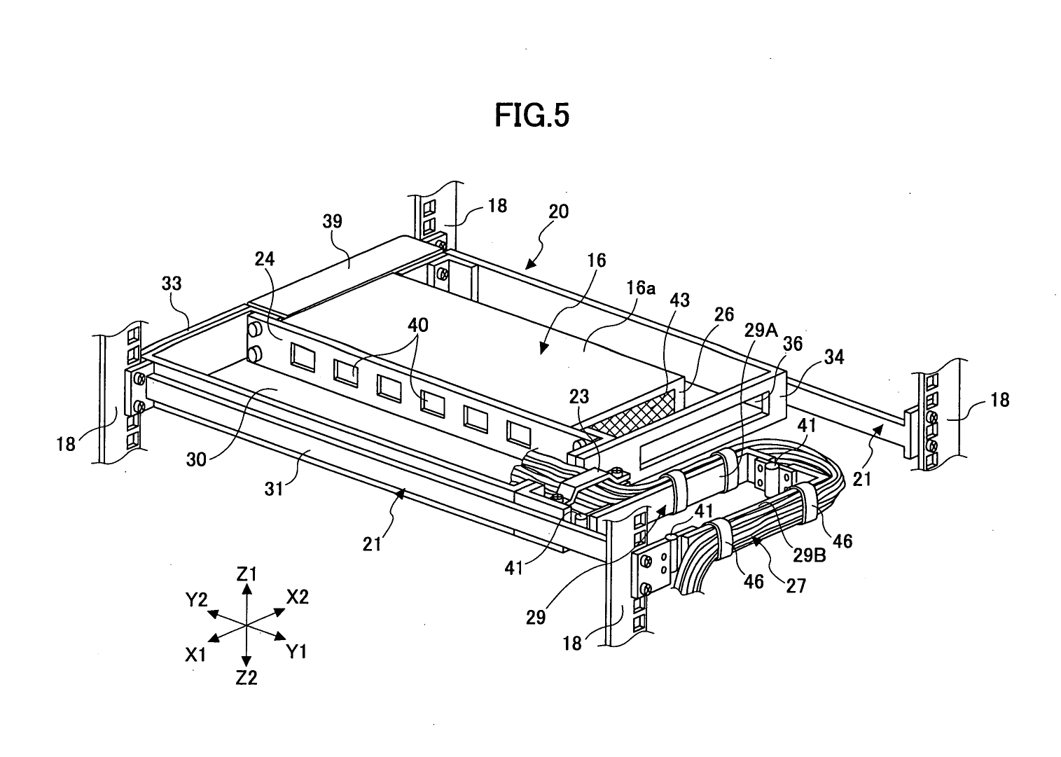

The electronic device 16 is the network product 11B as mentioned above, and is provided with plural connector attachment portions 40 (see FIGS. 5 and 6) on the operations face 24 extending in the longitudinal direction (the direction of the arrows Y1 and Y2) of a device main body 16a. Connector portions 44 provided at the end of signal cables 27 are attached to the connector attachment portions 40. The electronic device 16 is thus electrically connected to the signal cables 27. In the device main body 16a of the electronic device 16, an intake portion 42 is formed in a side face 25 at the Y2-direction side, and an exhaust portion 43 is formed in a side face 26 at the Y1-direction side.

The electronic device with the above-described configuration is mounted in the device mount member 20 such that the longitudinal direction of the device main body 16a is aligned with the direction of the cooling air flowing in the rack 12. In other words, the electronic device 16 is mounted such that the direction in which the operations face 24 extends is generally aligned with the direction of the arrows Y1 and Y2.

That is, the electronic device 16 is mounted in the device mount member 20 such that the side face 25 with the intake portion 42 opposes the front panel 33 and that the side face 26 with the exhaust portion 43 opposes the back panel 34. When the electronic device 16 is mounted in the device mount member 20 in this manner, the intake portion 42 and the exhaust portion 43 provided in the device main body 16a oppose the intake opening 35 formed in the front panel 33 and the exhaust opening 36 formed in the back panel 36, respectively (see FIGS. 5 and 8).

As mentioned above, since the rack 12 has a configuration of intake from the front and exhaust from the rear, cooling air 19 flows in the direction of the arrow Y1. Accordingly, the cooling air 19 flows into the intake portion 42 of the device main body 16a through the intake opening 35 of the front panel 33, flows through the inside of the device main body 16a to cool electronic components of the electronic device 16, and flows out of the exhaust portion 43 formed in the side face 26. The heated cooling air 19 flowing out of the exhaust portion 43 is exhausted outside the device mount member 20 through the exhaust opening 36 formed in the back panel 34.

According to this embodiment, even if the electronic device 16 is a network product configured such that the cooling air flow direction is aligned with the longitudinal direction of the device main body 16a, the cooling air 19 can flow from the intake portion 42 and flow out of the exhaust portion 43 by mounting the electronic device 16 in a manner such that the longitudinal direction of the device main body 16a is aligned with the fore-aft direction of the rack 12. Therefore, heat generating components in the electronic device 16 can surely be cooled.

When the electronic device 16 is mounted in the device mount member 20 such that the direction in which the operations face 24 extends is generally aligned with the direction of the arrows Y1 and Y2, a space is formed at each side (the X1 side and the X2 side) of the electronic device 16 in the device mount member 20. In this embodiment, a space 30 is formed in front of the operations face 24 of the electronic device 16 mounted in the device mount member 20. The signal cables 27 to be attached to the connector attachment portions 40 are connected to the connector attachment portions 40 by utilizing the space 30 (the space 30 is hereinafter referred to as a cable space 30).

Since the cable space 30 is formed at the position opposing the connector attachment portions 40, the signal cables 27 are disposed out of the way of other components in the device mount member 20. Also, the connector portions 44 provided at the end of the signal cables 27 can be easily attached to and detached from the connector attachment portions 40.

While the connector attachment portions 40 face the direction of the arrow X1, the signal cables 27 need to be pulled out in the direction of the arrow Y1 from the cable exit portion 37 of the device mount member 20. Therefore, the signal cables 27 need to be bent. However, since the cable space 30 is formed at the position opposing the connector attachment portions 40, there is no need to forcibly bend the signal cables 27, so that the signal cables 27 are not subjected to excessive strain.

The operations face 24 provided with the connector attachment portions 40 faces a direction (the X1 direction) different from the position of the rack front door 14 of the rack 12. Therefore, if the device mount member 20 is fixed to the rack 12, it is difficult to attach and detach the connector portions 44 of the signal cables 27 to and from the connector attachment portions 40 provided in the electronic device 16. To avoid this problem, in this embodiment, a slider 21 is provided so as to allow sliding movement of the device mount member 20 in the fore-aft directions (the directions of the arrows Y1 and Y2) of the rack 12.

The slider 21 comprises an expansion arm 29, a pair of fixed rails 31, and a pair of movable rails 32. The expansion arm 29 includes a first arm portion 29A, a second arm portion 29B, and first through third hinges 41. The first arm portion 29A is connected at one end to the device mount member 20 by the first hinge 41 and at the other end to one end of the second arm portion 29B by the second hinge 41. The other end of the second arm portion 29B is fixed to the angle mount 18 by the third hinge 41.

With this configuration, the expansion arm 29 is movable between a position where the first and second arm portions 29A and 29B are bent at the second hinge 41 in the middle of the expansion arm 29 and a position where the expansion arm 29 is generally linearly extended. The movement of the expansion arm 29 causes the device mount member 20 to move in the direction of the arrows Y1 and Y2. The signal cables 27 are not tied together at the inner side of the cable exit portion 37 formed in the device mount member 20 but are tied in a bundle at the outer side of the cable exit portion 37 by a cable holding portion 23.

The cables 27 are fixed to the expansion arm 29 (the first and second arm portions 29A and 29B) at the rear side of the position of the cable holding portion 23 by cable fixture bands 46. With this configuration, if there are a number of the signal cables 27 connected to the electronic device 16, the signal cables 27 do not impede the sliding movement of the device mount member 20. Moreover, since the signal cables 27 are held by the cable holding portion 23, the signal cables 27 (connector portions 44) are prevented from being pulled out of the device main body 16a due to the movement of the device mount member 20.

One of the fixed rails 31 is fixed between the angle mount 18 in the front left side and the angle mount 18 in the rear left side. The other fixed rail 31 is fixed between the angle mount 18 in the front right side and the angle mount 18 in the rear right side. The fixed rails 31 are provided with movable rails 32 slidable in the direction of the arrows Y1 and Y2. The movable rails 32 are disposed on the device mount member 20. That is, the device mount member 20 can be moved in the fore-aft directions (the Y1 and Y2 directions) of the rack 12 by the slider 21.

FIGS. 2 and 5 show the device mount member 20 accommodated in the rack 12. FIGS. 3 and 6 show the device mount member 20 pulled out of the rack 12. As can be seen, in this embodiment, when the device mount member 20 is pulled out of the rack 12, the electronic device 16 is pulled outside of the rack 12. Therefore, even though the operations face 24 is provided at the longitudinal side face of the device main body 16a, it is possible to attach and detach the connector portions 44 to and from the connector attachment portions 40 20 if the device mount member 20 is pulled out of the rack 12 using the slider 21. According to this embodiment, cooling the electronic device 16 is surely performed while facilitating handling of the electronic device 16 during maintenance or the like.

In the above described embodiment, although the device mount member 20 and the slider 21 are fixed to the angle mounts 18, the device mount member 20 and the slider 21 may be removably attached to the angle mounts 18. This configuration facilitates mounting of a network product and a storage product, etc., together in the rack 12.

In this case, a network product having a flow direction of the cooling air 19 inside a device main body thereof aligned with the longitudinal direction of the device main body and a storage product, etc., having a cooling air flow direction inside a device main body thereof generally orthogonal to the longitudinal direction of the device main body are mounted together in the rack 12.

With the above described configuration, the need for the cable accommodating spaces 101 of FIG. 4 is eliminated, so that electronic device mounting efficiency in the electronic apparatus 10 is enhanced.

What is claimed is:

1. An electronic apparatus configured so that cooling air flows between a front face and a rear face of a rack, the electronic apparatus comprising:
an electronic device that is provided with an operations portion at a longitudinal side face of a device main body and is cooled by the cooling air flowing inside the device main body in a longitudinal direction thereof;
a device mount member in which the electronic device is mounted so that the longitudinal direction of the device main body is aligned with a fore-aft direction of the rack; and
a slide mechanism that slides the device mount member in the fore-aft directions of the rack.

2. The electronic apparatus as claimed in claim 1, wherein the slide mechanism is removably attachable to the rack.

3. The electronic apparatus as claimed in claim 1,
wherein a connector attachment portion is provided as the operations portion at the longitudinal side face of the device main body; and
a wire accommodating space that accommodates a cable connected to the connector attachment portion is provided at a position opposing the connector attachment portion.

4. The electronic apparatus as claimed in claim 1, wherein the device mount member is provided with a cable holding portion that restricts movement of a cable connected to the electronic device.

5. The electronic apparatus as claimed in claim 1, wherein the slide mechanism includes a first rail fixed to the rack and a second rail slidable with respect to the first rail in the fore-aft directions of the rack.

6. The electronic apparatus as claimed in claim 1, wherein the electronic device is a network product.

7. The electronic apparatus as claimed in claim 1, wherein a first electronic device in which the cooling air flows in a device main body thereof in a longitudinal direction of the device main body thereof and a second electronic device in which the cooling air flows in a device main body thereof in a direction generally orthogonal to a longitudinal direction of the device main body thereof are mounted together in the rack.
